(19) United States
(12) Patent Application Publication
(10) Pub. No.: US 2025/0183243 A1
(43) Pub. Date: Jun. 5, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Hyunsoo Chung, Suwon-si (KR); Kwangsoo Kim, Suwon-si (KR); Chiwoo Lee, Suwon-si (KR)

(21) Appl. No.: 18/944,549

(22) Filed: Nov. 12, 2024

(30) Foreign Application Priority Data
Nov. 30, 2023 (KR) 10-2023-0171833

(51) Int. Cl. H01L 25/16; G02B 6/122; H01L 23/31; H01L 23/48; H01L 23/538; H10B 80/00

(52) U.S. Cl. CPC H01L 25/167; G02B 6/122; H01L 23/3135; H01L 23/481; H01L 23/5385; H10B 80/00

(57) ABSTRACT

A semiconductor package includes a package substrate, stack structures on the package substrate, a buffer chip on the package substrate and spaced apart from the stack structures in a horizontal direction, a memory controller chip stacked on the buffer chip, and a photonics package including a photonic integrated circuit (PIC) chip on the package substrate, an electronic integrated circuit (EIC) chip on the PIC chip, and a first molding layer surrounding the EIC chip. Each of the stack structures includes stacked core chips each including a memory cell, the buffer chip is configured to control the memory cell of each of the stacked core chips of each of the stack structures, and the memory controller chip is configured to interconnect the buffer chip to the photonics package.

### CROSS-REFERENCE TO RELATED APPLICATION

This application is based on and claims priority under 35 U.S.C. § 119 to Korean Patent Application No. 10-2023-0171833, filed on Nov. 30, 2023, in the Korean Intellectual Property Office, the disclosure of which is incorporated by reference herein in its entirety.

### BACKGROUND

The inventive concept relates to a semiconductor package and a method of manufacturing the same, and more particularly, to a semiconductor package including a photonic integrated circuit (PIC) chip and a method of manufacturing the semiconductor package.

The advantages of semiconductor packages are increasingly utilized to improve the functionality of electronic devices and integrate components therein. In a semiconductor package, various integrated circuits, such as memory chips or logic chips, may be mounted on a package substrate. Recently, with increasing data traffic in environments such as data centers and communication infrastructures, there has been ongoing research of semiconductor packages including PIC chips.

### SUMMARY

The inventive concept may provide a semiconductor package including a buffer chip with improved efficiency.

The inventive concept may provide a semiconductor package capable of easily controlling a memory chip stack.

Technical problems to be solved by the inventive concept are not limited to the above description, and other technical problems may be clearly understood by one of ordinary skill in the art from the descriptions provided hereinafter.

According to an aspect of the inventive concept, a semiconductor package includes a package substrate, a plurality of stack structures on the package substrate, a buffer chip on the package substrate and spaced apart from the plurality of stack structures in a horizontal direction, a memory controller chip stacked on the buffer chip, and a photonics package including a photonic integrated circuit (PIC) chip on the package substrate, an electronic integrated circuit (EIC) chip on the PIC chip, and a first molding layer surrounding the EIC chip. Each of the plurality of stack structures includes a plurality of stacked core chips each including a memory cell, the buffer chip is configured to control the memory cell of each of the plurality of stacked core chips, and the memory controller chip is configured to interconnect the buffer chip to the photonics package.

According to another aspect of the inventive concept, a semiconductor package includes a package substrate; a plurality of stack structures on the package substrate; a chip structure on the package substrate, spaced apart from the plurality of stack structures in a horizontal direction, the chip structure comprising a memory controller chip and a buffer chip which have different areas when viewed in plan view; and a photonics package configured to receive and/or transmit an optical signal from and/or to an external host, convert an optical signal into an electrical signal, and convert an electrical signal into an optical signal, wherein each of the plurality of stack structures comprises a plurality of stacked core chips each comprising a memory cell, the buffer chip of the chip structure is configured to control the memory cell of each of the plurality of stacked core chips of each of the plurality of stack structures, the memory controller chip of the chip structure is configured to interconnect the photonics package to the buffer chip, and the chip structure further comprises a molding layer surrounding a chip with a smaller area among the buffer chip and the memory controller chip.

According to another aspect of the inventive concept, a semiconductor package includes a package substrate; a plurality of stack structures on the package substrate; a chip structure on the package substrate, spaced apart from the plurality of stack structures in a horizontal direction, the chip structure comprising a buffer chip and a memory controller chip which have different areas from each other when viewed in plan view; a photonics package comprising: a photonic integrated circuit (PIC) chip on the package substrate, an electronic integrated circuit (EIC) chip on the PIC chip, and a first molding layer surrounding the EIC chip; and a third molding layer on the package substrate and surrounding the plurality of stack structures, the chip structure, and the photonics package, wherein the photonics package is configured to receive and/or transmit an optical signal from and/or to an external host and convert an optical signal into an electrical signal and an electrical signal into an optical signal, the memory controller chip of the chip structure is configured to convert an electrical signal that uses a first protocol, which has been converted from an optical signal by the photonics package, to an electrical signal that uses a second protocol, and to convert an electrical signal from the buffer chip that uses the second protocol to the electrical signal that uses the first protocol, each of the plurality of stack structures comprises a plurality of stacked core chips each comprising a dynamic random access memory (DRAM) cell, the buffer chip of the chip structure is configured to control the DRAM cell of each of the plurality of stacked core chips of each of the plurality of stack structures, the chip structure further comprises a second molding layer surrounding a chip with a smaller area among the buffer chip and the memory controller chip, the third molding layer contacts the second molding layer, and the third molding layer contacts the first molding layer.

### BRIEF DESCRIPTION OF THE DRAWINGS

Embodiments will be more clearly understood from the following detailed description taken in conjunction with the accompanying drawings in which:

FIG. 1 is a schematic plan view of a semiconductor package according to an embodiment;

FIG. 2 is a schematic cross-sectional view of the semiconductor package of FIG. 1, taken along a line A-A′ of FIG. 1;

FIG. 3 is an enlarged schematic cross-sectional view of a region EX1 of the semiconductor package of FIG. 2;

FIG. 4 is an enlarged schematic cross-sectional view of a region EX2 of the semiconductor package;

FIG. 5 is a schematic cross-sectional view of a semiconductor package according to an embodiment, taken along the line A-A′ of FIG. 1;

FIG. 6 is a schematic cross-sectional view of a semiconductor package according to an embodiment, taken along the line A-A′ of FIG. 1;

FIG. 7 is an enlarged schematic cross-sectional view of a region EX2d of the semiconductor package of FIG. 6;

FIG. 8 is a schematic cross-sectional view of a semiconductor package according to an embodiment, taken along the line A-A′ of FIG. 1;

FIG. 9 is a schematic cross-sectional view of a semiconductor package according to an embodiment, taken along the line A-A′ of FIG. 1;

FIG. 10 is a schematic cross-sectional view of a semiconductor package according to an embodiment, taken along the line A-A′ of FIG. 1;

FIG. 11 is a schematic cross-sectional view of a semiconductor package according to an embodiment, taken along the line A-A′ of FIG. 1;

FIG. 12 is a schematic plan view of a semiconductor package according to an embodiment; and

FIGS. 13 to 19 are diagrams showing a method of manufacturing a semiconductor package according to an embodiment.

### DETAILED DESCRIPTION OF THE EMBODIMENTS

As the disclosure allows for various changes and numerous embodiments, particular embodiments will be shown in the drawings and described in detail in the written description. However, it is not intended to limit the present embodiments to specific embodiments.

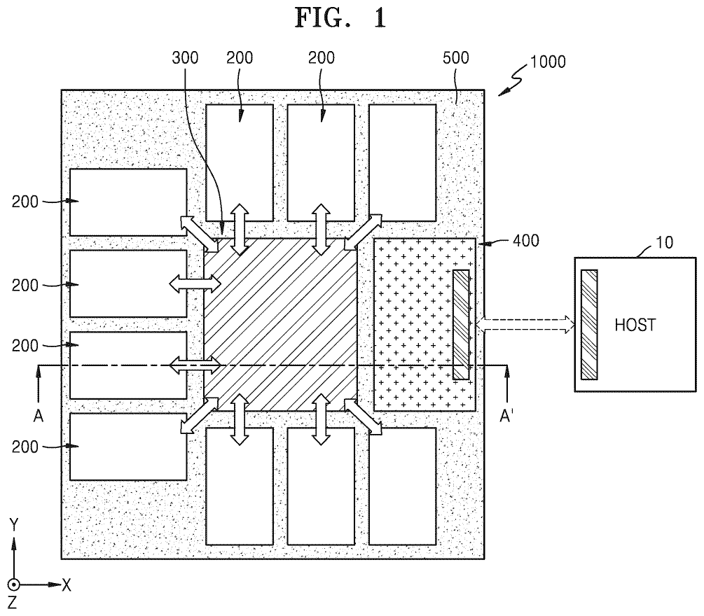

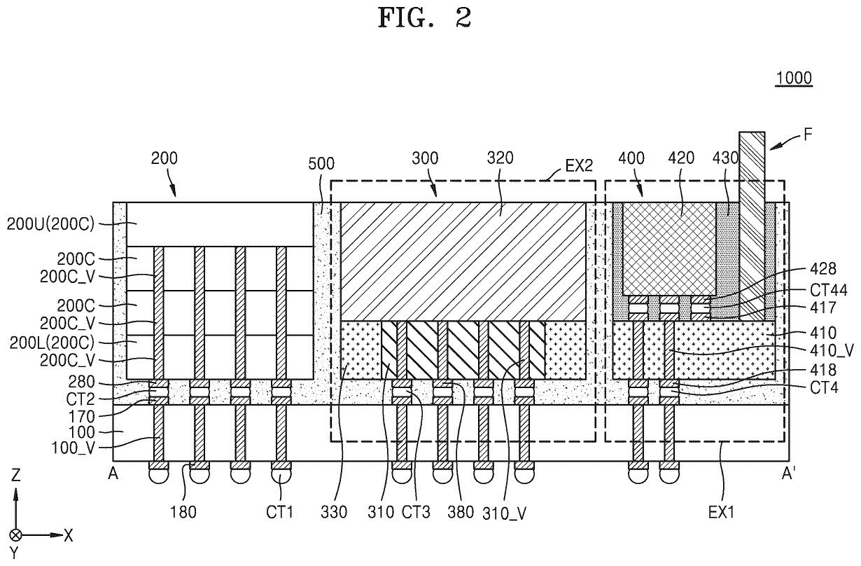

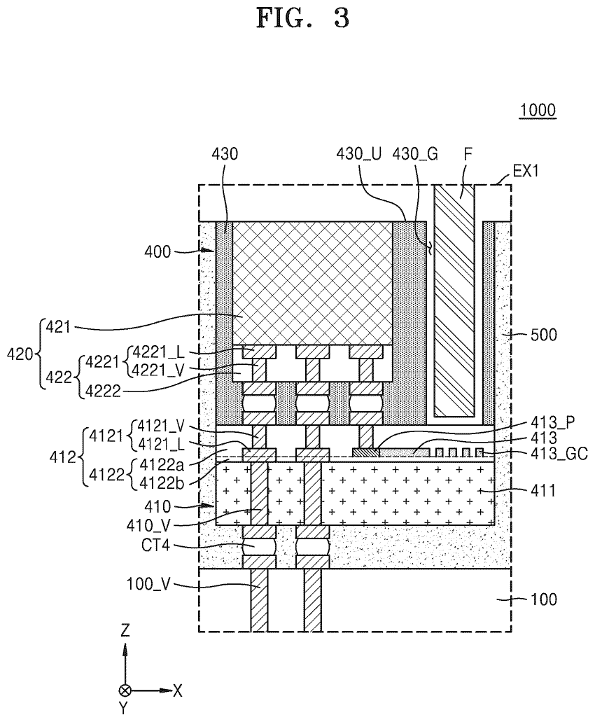

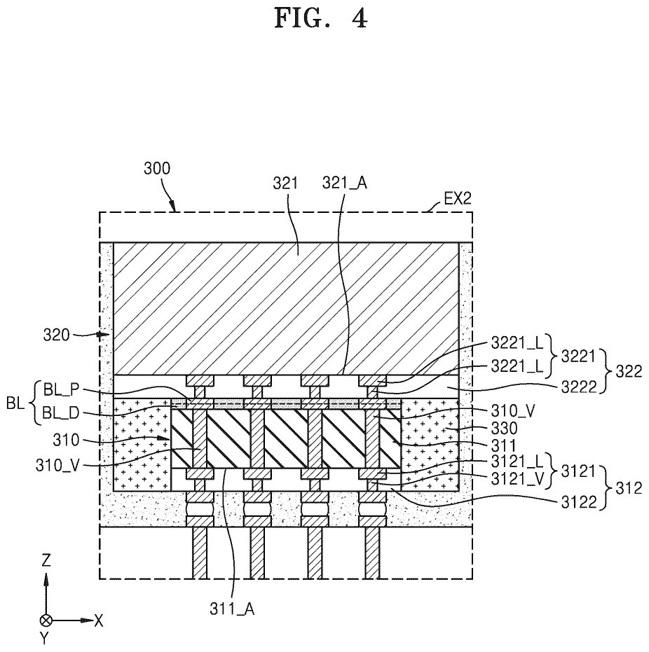

FIG. 1 is a schematic plan view of a semiconductor package 1000 according to an embodiment. FIG. 2 is a schematic cross-sectional view of the semiconductor package 1000 of FIG. 1, taken along a line A-A′ of FIG. 1. FIG. 3 is an enlarged schematic cross-sectional view of a region EX1 of the semiconductor package 1000 of FIG. 2. FIG. 4 is an enlarged schematic cross-sectional view of a region EX2 of the semiconductor package 1000, according to an embodiment.

Referring to FIGS. 1 to 4, the semiconductor package 1000 may include a package substrate 100, a plurality of stack structures 200, a chip structure 300, and a photonics package 400.

Hereinafter, unless otherwise specifically defined, a direction parallel to an upper surface of the package substrate 100 may be defined as a first horizontal direction (an X direction), a direction perpendicular to the upper surface of the package substrate 100 may be defined as a vertical direction (a Z direction), and a direction perpendicular to the first horizontal direction (the X direction) and the vertical direction (the Z direction) may be defined as a second horizontal direction (a Y direction). A combination of the first horizontal direction (the X direction) and the second horizontal direction (the Y direction) is defined as the horizontal direction.

The package substrate 100 may be an interposer including a substrate and a through via 100_V penetrating the substrate. For example, the package substrate 100 may be a glass interposer in which the substrate includes glass and the through via 100_V is a through glass via (TGV). However, one or more embodiments are not limited thereto. The package substrate 100 may be a silicon interposer in which the substrate includes silicon (Si) and the through via 100_V is a through silicon via (TSV).

In some embodiments, the package substrate 100 may be a redistribution structure including a redistribution pattern and a redistribution insulating layer surrounding the redistribution pattern.

The redistribution insulating layer may include an insulating material, for example, photo imageable dielectric (PID) resin. In some embodiments, the redistribution insulating layer may further include an inorganic filler. In some embodiments, the redistribution insulating layer may have a multilayered structure in which redistribution patterns are arranged at respective layers.

The redistribution pattern may include a redistribution line pattern extending in a horizontal direction and a redistribution via pattern extending from the redistribution line pattern in a vertical direction (the Z direction). The redistribution line pattern may be arranged on at least one of an upper surface and a lower surface of the redistribution insulating layer or arranged inside the redistribution insulating layer. The redistribution via pattern may penetrate the redistribution insulating layer and may be connected to portions of the redistribution line pattern.

The redistribution pattern may include a conductive material, for example, copper (Cu), aluminum (Al), silver (Ag), tin (Sn), gold (Au), nickel (Ni), lead (Pb), titanium (Ti), or an alloy thereof.

In some embodiments, the package substrate 100 may be a printed circuit board (PCB) that includes a core insulating layer including at least one material selected from among phenol resin, epoxy resin, and polyimide.

The package substrate 100 may include an upper pad 170 on the upper surface of the package substrate 100 and a lower pad 180 on the lower surface of the package substrate 100. The upper pad 170 may be electrically connected to the lower pad 180 through the through via 100_V. However, one or more embodiments are not limited thereto. The upper pad 170 may be electrically connected to the lower pad 180 through the redistribution pattern or an internal line. In some embodiments, the upper pad 170 and the lower pad 180 may each include Cu, Ni, stainless steel, or beryllium copper.

External connection terminals CT1 may be respectively attached to the lower pads 180. The external connection terminals CT1 may be configured to electrically and physically connect the package substrate 100 to an external device in or on which the package substrate 100 is mounted. The external connection terminals CT1 may be formed from, for example, solder balls or solder bumps.

However, one or more embodiments are not limited thereto, and the package substrate 100 may be mounted in a socket in an external device. That is, the package substrate 100 may be electrically and physically connected to the external device without the external connection terminals CT1.

The stack structures 200 may be arranged on the package substrate 100. The stack structures 200 may be spaced apart from each other in the horizontal direction. For example, the stack structures 200 may surround the chip structure 300.

Each stack structure 200 may include a plurality of core chips 200C stacked in the vertical direction (the Z direction). Each core chip 200C may include a memory cell. For example, each core chip 200C may be a type of memory semiconductor chip.

In some embodiments, the core chips 200C may all be the same type of memory semiconductor chip. For example, the core chips 200C may each be a dynamic random access memory (DRAM) semiconductor chip.

Each core chip 200C may include, for example, a semiconductor material, such as Si or germanium (Ge). Alternatively, each core chip 200C may include a compound semiconductor material, such as silicon carbide (SiC), gallium arsenide (GaAs), indium arsenide (InAs), or indium phosphide (InP).

Each core chip 200C may include an active surface and an inactive surface opposite thereto. On the active surface of each core chip 200C, a semiconductor device including various types of individual devices may be formed. Each core chip 200C may include a conductive region, that is, a well doped with impurities. Each core chip 200C may have a device isolation structure, such as a shallow trench isolation (STI) structure.

The individual devices on the active surface of each core chip 200C may be electrically connected to the conductive region. For example, each core chip 200C may further include a conductive line or a conductive plug configured to electrically connect the individual devices to the conductive region. In addition, the individual devices may be electrically separated from other neighboring individual devices by insulating layers, respectively.

Each core chip 200C may include a memory semiconductor chip including a memory cell. For example, the memory cell may be a non-volatile memory cell, such as flash memory, phase-change random access memory (PRAM), magneto-resistive random access memory (MRAM), ferroelectric random access memory (FeRAM), or resistive random access memory (RRAM). In some embodiments, the memory cell may be a volatile memory cell, such as DRAM or static random access memory (SRAM).

In some embodiments, a core chip that is the uppermost among the core chips 200C may be referred to as an uppermost core chip 200U, and a core chip that is the lowermost among the core chips 200C may be referred to as a lowermost core chip 200L. FIG. 2 shows that four core chips are stacked in each stack structure 200, but the number of core chips included in the stack structures 200 is not limited thereto.

In some embodiments, a lower pad 280 may be on the lower surface of the lowermost core chip 200L. The lower pad 280 of the lowermost core chip 200L may be electrically connected to a through via 200C_V of the lowermost core chip 200L or to the conductive region.

The lower pad 280 of the lowermost core chip 200L may be electrically connected to the upper pad 170 of the package substrate 100 through a connection terminal CT2. However, one or more embodiments are not limited thereto, and the lower pad 280 of the lowermost core chip 200L may be electrically connected to the upper pad 170 of the package substrate 100 through an ACF, an NCF, direct bonding, or hybrid bonding.

In some embodiments, a semiconductor chip except the uppermost core chip 200U among the core chips 200C may further include the through via 200C_V extending from the upper surface of the semiconductor chip to the inside thereof. The through via 200C_V of each core chip 200C may be electrically connected to the conductive region of each core chip 200C. However, one or more embodiments are not limited thereto, and the uppermost core chip 200U may also include the through via 200C_V.

Each core chip 200C may be electrically connected to a neighboring core chip through the through via 200C_V. Accordingly, the core chips 200C may be electrically connected to the package substrate 100 through the through vias 200C_V. For example, the conductive region of the uppermost core chip 200U may be electrically connected to the package substrate 100 through the through vias 200C_V of the semiconductor chips stacked under the uppermost core chip 200U.

In some embodiments, a thickness of each core chip 200C, that is, a length thereof in the vertical direction (the Z direction), may be between about 20 μm and about 80 μm. The thicknesses of the core chips 200C may be substantially the same.

In some embodiments, each stack structure 200 may further include a stack dummy chip (not shown). The stack dummy chip may be stacked on the uppermost core chip 200U. The stack dummy chip may include a semiconductor material, such as Si. In some embodiments, the stack dummy chip may include only a semiconductor material. For example, the stack dummy chip may be a portion of a bare wafer.

The photonics package 400 may be arranged on the package substrate 100. The photonics package 400 may be electrically connected to the package substrate 100. The photonics package 400 may be electrically connected to the chip structure 300 through the package substrate 100. The photonics package 400 is described in detail with reference to FIG. 3.

The photonics package 400 may include a photonic integrated circuit (PIC) chip 410, an electronic integrated circuit (EIC) chip 420, and a first molding layer 430. The photonics package 400 may convert an optical signal into an electrical signal and an electrical signal into an optical signal. For example, the photonics package 400 may exchange an electrical signal with the chip structure 300 and an optical signal with optical fiber F.

The PIC chip 410 may be on the package substrate 100. For example, the PIC chip 410 may be on the lowermost portion of the photonics package 400. In some embodiments, the vertical level of the lower surface of the PIC chip 410 may be the same as the vertical level of the lower surface of the chip structure 300.

The PIC chip 410 may include a first substrate 411, a first wiring structure 412, and a waveguide 413. For example, the first wiring structure 412 and the waveguide 413 may be on an upper surface of the first substrate 411. For example, the first substrate 411 may include a first through via 410_V extending from an upper surface of the first substrate 411 to a lower surface thereof.

In some embodiments, the first substrate 411 may include a semiconductor material, such as Si. Alternatively, the first substrate 411 may include a semiconductor material, such as Ge.

The first wiring structure 412 may include a first wiring pattern 4121 and a first wiring insulating layer 4122 surrounding the first wiring pattern 4121. The first wiring pattern 4121 may include a first wiring line 4121_L extending in the horizontal direction and a first wiring via 4121_V extending from the first wiring line 4121_L in the vertical direction (the Z direction). The first wiring pattern 4121 may be electrically connected to the first through via 410_V.

The first wiring insulating layer 4122 may be divided into a lower wiring insulating layer 4122b and an upper wiring insulating layer 4122a. In some embodiments, the lower wiring insulating layer 4122b may be an oxide layer including silicon oxide or the like. The upper wiring insulating layer 4122a may be one or more dielectric layers including silicon oxide, silicon nitride, or a combination thereof. In some embodiments, the lower wiring insulating layer 4122b may include the same material as the upper wiring insulating layer 4122a.

The waveguide 413 may be a patterned silicon layer and may horizontally extend on the lower wiring insulating layer 4122b. For example, the waveguide 413 may be buried in the first wiring insulating layer 4122. For example, the waveguide 413 may be on the lower wiring insulating layer 4122b and covered by the upper wiring insulating layer 4122a. In some embodiments, the waveguide 413 may be a silicon waveguide, and the first wiring insulating layer 4122 may be a buried oxide (BOX) layer. However, one or more embodiments are not limited thereto, and the waveguide 413 may be covered by an oxide layer that is distinguished from the first wiring insulating layer 4122.

The waveguide 413 may be connected to a photonic component 413_P. For example, a surface on which the photonic component 413_P is located may be referred to as an active surface of the first substrate 411. The photonic component 413_P may convert an optical signal into an electrical signal and an electrical signal into an optical signal. In some embodiments, the photonic component 413_P may include a photodetector, laser diodes, and a modulator.

In the process whereby an optical signal is input to the photonics package 400, the photodetector may detect the optical signal that is input to the PIC chip 410. The PIC chip 410 may detect the input optical signal through the photodetector and may convert the same into an electrical signal.

While the photonics package 400 outputs the optical signal, the EIC chip 420 may transmit the electrical signal to the modulator. The modulator may input a signal corresponding to a received electrical signal into light emitted from the laser diode and may convert the electrical signal into an optical signal.

The PIC chip 410 may further include a lower pad 418 and an upper pad 417 (see, e.g., FIG. 2). The lower pad 418 may be on the lower surface of the first substrate 411 and electrically connected to the first through via 410_V. The upper pad 417 may be on the upper surface of the first wiring structure 412 and electrically connected to the first wiring pattern 4121.

The lower pad 418 of the PIC chip 410 may be electrically connected to the upper pad 170 of the package substrate 100 through a connection terminal CT4. However, one or more embodiments are not limited thereto, and the lower pad 418 of the PIC chip 410 may be electrically connected to the upper pad 170 of the package substrate 100 through an ACF, an NCF, direct bonding, or hybrid bonding.

The EIC chip 420 may be on the PIC chip 410. For example, the EIC chip 420 may overlap the first through via 410_V of the PIC chip 410 in the vertical direction (the Z direction).

The EIC chip 420 may include a second substrate 421 and a second wiring structure 422. The second substrate 421 of the EIC chip 420 may include an active surface and an inactive surface opposite thereto. The second wiring structure 422 may be formed on the active surface of the second substrate 421.

The second substrate 421 may include a semiconductor material, such as Si. Alternatively, the second substrate 421 may include a semiconductor material, such as Ge.

In some embodiments, the EIC chip 420 may include a plurality of individual devices used to interface the EIC chip 420 with the PIC chip 410. The individual devices of the EIC chip 420 may be arranged on the active surface of the second substrate 421. For example, the EIC chip 420 may include CMOS drivers, trans-impedance amplifiers, and the like to perform a function of controlling the high-frequency signaling of the PIC chip 410.

The second wiring structure 422 may include a second wiring pattern 4221 and a second wiring insulating layer 4222 surrounding the second wiring pattern 4221. The second wiring pattern 4221 may include a second wiring line 4221_L extending in the horizontal direction and a second wiring via 4221_V extending from the second wiring line 4221_L in the vertical direction (the Z direction). The second wiring pattern 4221 may be electrically connected to the individual devices.

In some embodiments, the EIC chip 420 may be arranged on the PIC chip 410 to make the active surface of the second substrate 421 face the PIC chip 410. For example, the EIC chip 420 may be arranged on the PIC chip 410 in a face-down manner.

The EIC chip 420 may further include a lower pad 428. The lower pad 428 may be on the lower surface of the second wiring structure 422 and electrically connected to the second wiring pattern 4221.

The lower pad 428 of the EIC chip 420 may be electrically connected to the upper pad 417 of the PIC chip 410 through a connection terminal CT44. However, one or more embodiments are not limited thereto, and the lower pad 428 of the EIC chip 420 may be electrically connected to the upper pad 417 of the PIC chip 410 through an ACF, an NCF, direct bonding, or hybrid bonding.

For example, the electrical signal converted by the photonics package 400 may be transmitted to the chip structure 300 through the package substrate 100 and the through via 410_V. In some embodiments, the photonics package 400 may be electrically connected to a physical layer (PHY) of the buffer chip 310 of the chip structure 300.

The first molding layer 430 may be on the PIC chip 410 and may surround the EIC chip 420. The area of the PIC chip 410 when viewed in plan view may be greater than the area of the EIC chip 420. The first molding layer 430 may fill a portion of an upper portion of the PIC chip 410, on which the EIC chip 420 is not stacked. Hereinafter, the term “area” may refer to an area of a surface parallel to a horizontal plane, that is, an X-Y plane.

For example, the first molding layer 430 may include epoxy resin, polyimide resin, or the like. The first molding layer 430 may include, for example, an epoxy mold compound (EMC).

For example, an outer sidewall of the first molding layer 430 may be coplanar with an outer sidewall of the PIC chip 410. An upper surface 430_U of the first molding layer 430 may be coplanar with the upper surface of the EIC chip 420. For example, the vertical level of the upper surface 430_U of the first molding layer 430 may be the same as the vertical level of the upper surface of the EIC chip 420. That is, the upper surface of the EIC chip 420 may be externally exposed from the first molding layer 430. Accordingly, the semiconductor package 1000 may facilitate the easy discharge of heat generated by the EIC chip 420.

It will be appreciated that “coplanar”, etc., as used herein refer to structures (e.g., surfaces) that need not be perfectly geometrically planar, but may include acceptable variances that may result from standard manufacturing processes.

The first molding layer 430 may further include an opening 430_G. The opening 430_G may extend from the upper surface of the first molding layer 430 to the inside thereof. The opening 430_G may be located above the waveguide 413 such that a portion of the waveguide 413 may be exposed to the outside through the opening 430_G. In some embodiments, the waveguide 413 may further include a grating coupler 413_GC, and the grating coupler 413_GC may be on the portion of the waveguide 413 that is externally exposed through the opening 430_G.

In some embodiments, the optical fiber F may be arranged inside the opening 430_G of the first molding layer 430. The optical fiber F may be located above the waveguide 413. For example, the optical fiber F may receive and/or transmit an optical signal from and/or to the waveguide 413. The optical fiber F may be optically connected to the waveguide 413 through the grating coupler 413_GC. In some embodiments, the optical fiber F may be a fiber array unit (FAU).

However, one or more embodiments are not limited thereto, and the PIC chip 410 of the photonics package 400 may include a V-groove (not shown) extending from a side surface of the PIC chip 410 to the inside thereof. An end of the waveguide 413 may be exposed to the outside through the V-groove, and the optical fiber F may be located inside the V-groove.

The chip structure 300 may be on the package substrate 100. The chip structure 300 may be spaced apart from the stack structures 200 and the photonics package 400 in the horizontal direction. For example, the chip structure 300 may be located in a central region of the upper surface of the package substrate 100, and the photonics package 400 and the stack structures 200 may be located in edge regions of the upper surface of the package substrate 100. For example, a distance from a stack structure 200 to a nearest edge of the semiconductor package 1000 may be smaller than a distance from the chip structure 300 to the nearest edge of the semiconductor package 1000, and a distance from the photonics package 400 to a nearest edge of the semiconductor package 1000 may be smaller than the distance from the chip structure 300 to the nearest edge of the semiconductor package 1000.

The chip structure 300 is described in detail with reference to FIG. 4.

The chip structure 300 may include a buffer chip 310, a memory controller chip 320, and a second molding layer 330. The chip structure 300 may be a stack structure in which the buffer chip 310 and the memory controller chip 320 are stacked in the vertical direction (the Z direction).

It is illustrated that the chip structure 300 includes one buffer chip 310 and one memory controller chip 320, but one or more embodiments are not limited thereto. The chip structure 300 may include a plurality of buffer chips 310 that are spaced apart from each other in the horizontal direction, and one memory controller chip 320 may be arranged on the buffer chips 310.

In some embodiments, the area of the memory controller chip 320 when viewed in plan view may be different from the area of the buffer chip 310. The second molding layer 330 may surround a chip with a smaller area among the memory controller chip 320 and the buffer chip 310. In some embodiments, however, the chip structure 300 may not include the second molding layer 330 when the area of the memory controller chip 320 is the same as that of the buffer chip 310.

In some embodiments, the buffer chip 310 may be arranged on the package substrate 100, and the memory controller chip 320 may be arranged on the buffer chip 310. In some embodiments, the second molding layer 330 may be arranged on the package substrate 100 and may surround the buffer chip 310.

In some embodiments, the area of the buffer chip 310 may be less than that of the memory controller chip 320. The second molding layer 330 may be arranged between the package substrate 100 and the memory controller chip 320, surround the buffer chip 310, and have an outer side surface that is coplanar with the side surface of the memory controller chip 320.

The buffer chip 310 may include a plurality of individual devices used to control the stack structures 200. The buffer chip 310 may control a memory cell of each core chip 200C of each stack structure 200. For example, the buffer chip 310 may be electrically connected to the stack structures 200. The buffer chip 310 may be electrically connected to all of the stack structures 200 through the package substrate 100. For example, the buffer chip 310 may perform input/output (I/O) and physical (PHY) layer functions with respect to the stack structures 200.

The memory controller chip 320 may include a plurality of individual devices used to convert protocols of electrical signals. For example, the memory controller chip 320 may help communication between an external host 10 and the buffer chip 310. That is, the memory controller chip 320 may interconnect the buffer chip 310 to the external host 10. For example, the memory controller chip 320 may convert an electrical signal that uses a first protocol, which has been converted from an optical signal by the photonics package 400, to an electrical signal that uses a second protocol and transmit the electrical signal that uses the second protocol to the buffer chip 310. For example, the memory controller chip 320 may convert the electrical signal from the buffer chip 310 that uses the second protocol to the electrical signal that uses the first protocol and transmit the electrical signal that uses the first protocol to the photonics package 400.

The memory controller chip 320 may convert the protocols of the electrical signals that have been converted from optical signals by the photonics package 400. For example, protocols of optical signals that are input to the photonics package 400 from the external host 10 may be different from the protocols of the buffer chip 310. The memory controller chip 320 may convert the protocols of the signals from the external host 10 to match with the protocols of the signals from the buffer chip 310.

In some embodiments, the memory controller chip 320 may convert the protocols of the electrical signals from the photonics package 400 and transmit the converted protocols to the buffer chip 310. In addition, the memory controller chip 320 may convert the protocols of the electrical signals from the buffer chip 310 and transmit the converted protocols to the photonics package 400.

In some embodiments, digital data communication between the external host 10 and the buffer chip 310 through the memory controller chip 320 may be implemented according to digital data interconnect standards, for example, Peripheral Component Interconnect Express (PCIe) standards, Compute Express Link (CXL), Gen-Z standards, Open Coherent Accelerator Processor Interface (OpenCAPI), and/or Open Memory Interface (OMI).

The buffer chip 310 may include a third substrate 311, a third through via 310_V, and a third wiring structure 312. The third substrate 311 may include an active surface 311_A and an inactive surface opposite thereto, and the third wiring structure 312 may be arranged on the active surface 311_A of the third substrate 311.

The third through via 310_V may extend from the inactive surface of the third substrate 311 to the active surface 311_A thereof. For example, the third through via 310_V may be electrically connected to the third wiring structure 312 and/or a bonding pad BL_P. For example, the third through via 310_V may electrically connect the memory controller chip 320 to the package substrate 100 and the buffer chip 310.

The memory controller chip 320 may include a fourth substrate 321 and a fourth wiring structure 322. The fourth substrate 321 may include an active surface 321_A and an inactive surface opposite thereto, and the fourth wiring structure 322 may be arranged on the active surface 321_A of the fourth substrate 321.

The third substrate 311 and the fourth substrate 321 may each include a semiconductor material, such as Si. Alternatively, the third substrate 311 and the fourth substrate 321 may each include a semiconductor material, such as Ge. The individual devices of the buffer chip 310 may be arranged on the active surface 311_A of the third substrate 311. The individual devices of the memory controller chip 320 may be arranged on the active surface 321_A of the fourth substrate 321.

The individual devices of each of the buffer chip 310 and the memory controller chip 320 may include various microelectronic devices, for example, a metal-oxide-semiconductor field effect transistor (MOSFET) such as a complementary metal-oxide-semiconductor (CMOS) transistor, an image sensor such as system large scale integration (LSI) or an CMOS imaging sensor (CIS), a micro-electro-mechanical system (MEMS), an active element, and a passive element.

The third wiring structure 312 may include a third wiring pattern 3121 and a third wiring insulating layer 3122 surrounding the third wiring pattern 3121. The third wiring pattern 3121 may include a third wiring line 3121_L extending in the horizontal direction and a third wiring via 3121_V extending from the third wiring line 3121_L in the vertical direction (the Z direction). The third wiring pattern 3121 may be electrically connected to the individual devices.

The fourth wiring structure 322 may include a fourth wiring pattern 3221 and a fourth wiring insulating layer 3222 surrounding the fourth wiring pattern 3221. The fourth wiring pattern 3221 may include a fourth wiring line 3221_L extending in the horizontal direction and a fourth wiring via 3221_V extending from the fourth wiring line 3221_L in the vertical direction (the Z direction). The fourth wiring pattern 3221 may be electrically connected to the individual devices.

For example, the buffer chip 310 may include a serial-parallel conversion circuit, each stack structure 200 may be a memory semiconductor chip including a memory cell, and the memory controller chip 320 may transmit data to the buffer chip 310 to control the stack structures 200. For example, the buffer chip 310 may be referred to as an HBM controller die, each stack structure 200 may be referred to as a DRAM stack, and the memory controller chip 320 may be referred to as a CXL controller.

In some embodiments, the buffer chip 310 may be arranged on the package substrate 100 such that the active surface 311_A of the third substrate 311 faces the package substrate 100. For example, the buffer chip 310 may be arranged on the package substrate 100 in a face-down manner. However, one or more embodiments are not limited thereto, and the buffer chip 310 may be arranged on the package substrate 100 in a face-up manner.

In some embodiments, the memory controller chip 320 may be arranged on the buffer chip 310 such that the active surface 321_A of the fourth substrate 321 faces the package substrate 100. For example, the buffer chip 310 may be arranged on the package substrate 100 in a face-down manner.

In some embodiments, a bonding layer BL may be arranged between the memory controller chip 320 and the buffer chip 310. The bonding layer BL may be surrounded by the second molding layer 330. The bonding layer BL may include a bonding pad BL_P and a bonding insulating layer BL_D surrounding the bonding pad BL_P. In some embodiments, the bonding pad BL_P may be electrically connected to the fourth wiring structure 322 of the memory controller chip 320 and the third through via 310_V of the buffer chip 310.

In some embodiments, the bonding pad BL_P may be formed as a connection pad of the memory controller chip 320 is diffusion-bonded to a connection pad of the buffer chip 310 through heat. In the process of forming the bonding pad BL_P, the bonding insulating layer BL_D may be formed as an insulating layer surrounding the connection pad of the memory controller chip 320 is diffusion-bonded to an insulating layer surrounding the connection pad of the buffer chip 310 through heat.

That is, the memory controller chip 320 may be bonded to the buffer chip 310 through hybrid bonding. However, one or more embodiments are not limited thereto, and the memory controller chip 320 may be electrically connected to the buffer chip 310 through a connection terminal such as a solder ball or a conductive film such as an ACF or an NCF.

The buffer chip 310 may further include a lower pad 380. The lower pad 380 may be arranged on the lower surface of the third wiring structure 312 and may be electrically connected to the third wiring pattern 3121 and/or the third through via 310_V.

The lower pad 380 of the buffer chip 310 may be electrically connected to the upper pad 170 of the package substrate 100 through a connection terminal CT3. However, one or more embodiments are not limited thereto, and the lower pad 380 of the buffer chip 310 may be electrically connected to the upper pad 170 of the package substrate 100 through an ACF, an NCF, direct bonding, or hybrid bonding.

Referring back to FIGS. 1 and 2, in some embodiments, the photonics package 400 and the stack structures 200 may surround the chip structure 300. For example, the stack structures 200 and the photonics package 400 may be in edge regions of the package substrate 100, and the chip structure 300 may be in a central region of the package substrate 100. In some embodiments, for example, one side surface of the chip structure 300 may face the photonics package 400, and the other side surfaces may face the stack structures 200.

In some embodiments, the stack structures 200 may be arranged in a U shape. The stack structures 200 may surround the photonics package 400 and the chip structure 300. For example, the photonics package 400 and the chip structure 300 may be arranged in a region surrounded by the stack structures 200. For example, when a side surface of the photonics package 400, which faces the buffer chip from among the side surfaces of the photonics package 400, is a first side surface, a side surface adjacent to the first side surface of the photonics package 400 may face the stack structures, and a side surface opposite to the first side surface may face the outside of the semiconductor package 1000 (sec, e.g., FIG. 1).

In some embodiments, the area of each stack structure 200 may be less than the area of the chip structure 300. For example, a length of each stack structure 200 in a first horizontal direction (an X direction) and/or a second horizontal direction (a Y direction) may be less than a length of the chip structure 300 in the first horizontal direction (the X direction) and/or the second horizontal direction (the Y direction).

In some embodiments, the semiconductor package 1000 may further include a third molding layer 500. The third molding layer 500 may be arranged on the package substrate 100 and surround the stack structures 200, the chip structure 300, and the photonics package 400. For example, the side surface of each of the stack structures 200, the chip structure 300, and the photonics package 400 may be covered by the third molding layer 500.

For example, the third molding layer 500 may include epoxy resin, polyimide resin, or the like. The third molding layer 500 may include, for example, an EMC.

In some embodiments, an interface may exist between the third molding layer 500 and the first molding layer 430. For example, because the curing timing of the third molding layer 500 is different from the curing timing of the first molding layer 430, there may be an interface between the third molding layer 500 and the first molding layer 430. That is, as the first molding layer 430 is cured and then the third molding layer 500 is cured after a certain interval, there may be an interface between the first molding layer 430 and the third molding layer 500. For example, the third molding layer 500 may contact the first molding layer 430.

It will be understood that when an element is referred to as “contacting” or “in contact with” another element (or using any form of the word “contact”), there are no intervening elements present at the point of contact.

In some embodiments, an interface may exist between the third molding layer 500 and the second molding layer 330. For example, because the curing timing of the third molding layer 500 is different from the curing timing of the second molding layer 330, there may be an interface between the third molding layer 500 and the second molding layer 330. That is, as the second molding layer 330 is cured and then the third molding layer 500 is cured after a certain interval, there may be an interface between the second molding layer 330 and the third molding layer 500. For example, the third molding layer 500 may contact the second molding layer 330.

In some embodiments, the area of the third molding layer 500 may be the same as the area of the package substrate 100. For example, the outer side surface of the third molding layer 500 may be coplanar with the outer side surface of the package substrate 100.

In some embodiments, the upper surface of the third molding layer 500 may be coplanar with the upper surface of the chip structure 300. For example, the vertical level of the upper surface of the third molding layer 500 may be the same as the vertical level of the upper surface of the chip structure 300. The upper surface of the chip structure 300 may be externally exposed. Accordingly, the semiconductor package 1000 may facilitate the easy discharge of heat generated by the chip structure 300.

In some embodiments, the upper surface of the third molding layer 500 may be coplanar with the upper surface of the photonics package 400. For example, the vertical level of the upper surface of the third molding layer 500 may be the same as the vertical level of the upper surface of the EIC chip 420 and the vertical level of the upper surface of the first molding layer 430. The upper surface of the EIC chip 420 may be externally exposed. Accordingly, the semiconductor package 1000 may facilitate the easy discharge of heat generated by the EIC chip 420.

The semiconductor package 1000 may exchange a broad bandwidth (for example, with an external host 10) through the photonics package 400, and thus, data transmission speed may increase. Because one buffer chip 310 may control the stack structures 200, the size of the semiconductor package 1000 may be relatively reduced, and the data process speed may increase. Moreover, the memory use efficiency of each stack structure 200 may be improved by controlling the buffer chip 310 through the memory controller chip 320. Further, a connection distance constraint with the host may be removed by the positioning of the photonics package 400, the buffer chip 310, and the memory controller chip 320.

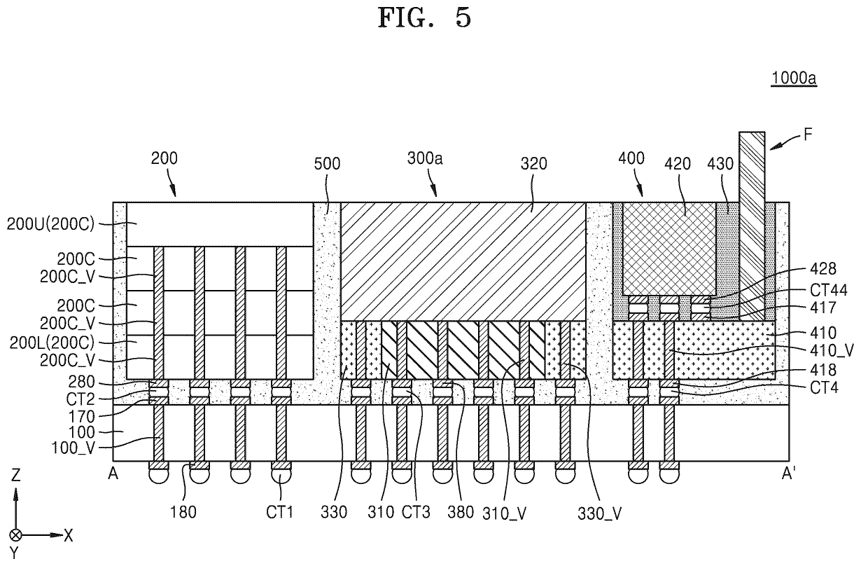

FIG. 5 is a schematic cross-sectional view of a semiconductor package 1000a according to an embodiment, taken along the line A-A′ of FIG. 1.

Most of the components forming the semiconductor package 1000a described below and the materials of the components are substantially the same as or similar to those described above with reference to FIG. 2. Therefore, for convenience of explanation, differences between the semiconductor package 1000a of FIG. 5 and the aforementioned semiconductor package 1000 of FIG. 2 are mainly described.

The semiconductor package 1000a may include a chip structure 300a. The chip structure 300a may include a buffer chip 310, a memory controller chip 320, and a second molding layer 330. The chip structure 300a may further include a through electrode 330_V. For example, the through electrode 330_V may extend through the second molding layer 330 from an upper surface of the second molding layer 330 to a lower surface thereof.

In some embodiments, a portion of the lower pad 380 may be located under the through electrode 330_V and thus electrically connected thereto. The through electrode 330_V may be electrically connected to the package substrate 100 in the same manner as the manner in which the buffer chip 310 is electrically connected to the package substrate 100. The through electrode 330_V may electrically connect the package substrate 100 to the memory controller chip 320.

An input/output terminal of the memory controller chip 320 may be arranged on an upper portion of the second molding layer 330. That is, the input/output terminal of the memory controller chip 320 may be arranged on the through electrode 330_V as well as the third through via 310_V. Accordingly, the number of input/output terminals of the memory controller chip 320 increases, or the density of the memory controller chip 320 decreases such that the accuracy of signals may be enhanced.

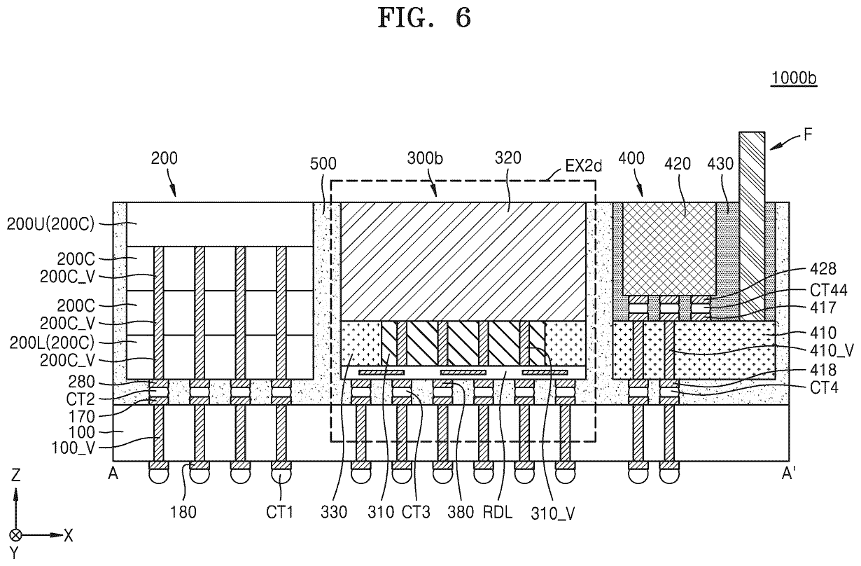

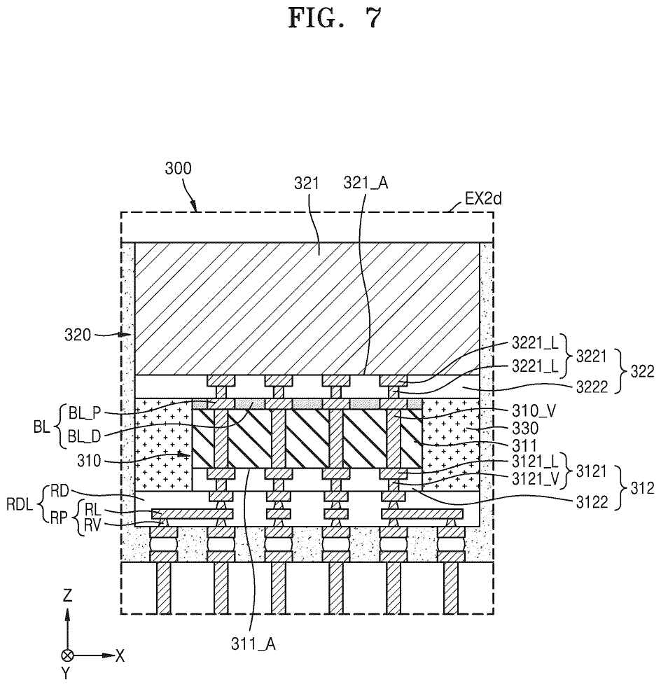

FIG. 6 is a schematic cross-sectional view of a semiconductor package 1000b according to an embodiment, taken along the line A-A′ of FIG. 1. FIG. 7 is an enlarged schematic cross-sectional view of a region EX2d of the semiconductor package 1000b of FIG. 6.

Most of the components forming the semiconductor package 1000b described below and the materials of the components are substantially the same as or similar to those described above with reference to FIG. 2. Therefore, for convenience of explanation, differences between the semiconductor package 1000b of FIG. 6 and the aforementioned semiconductor package 1000 of FIG. 2 are mainly described.

The semiconductor package 1000b may include a chip structure 300b. The chip structure 300b may be horizontally spaced apart from the stack structures 200 and the photonics package 400 on the package substrate 100. The chip structure 300b may further include the buffer chip 310, the memory controller chip 320, the second molding layer 330, and a redistribution layer RDL.

The area of the memory controller chip 320 may be greater than that of the buffer chip 310, and the side surface of the buffer chip 310 may be located under the lower portion of the memory controller chip 320. The second molding layer 330 may be located on (e.g., may contact) the lower portion of the memory controller chip 320 and may surround the buffer chip 310. The outer side surface of the second molding layer 330 may be coplanar with the side surface of the memory controller chip 320. The lower surface of the second molding layer 330 may be coplanar with the lower surface of the buffer chip 310.

The redistribution layer RDL may be arranged under the buffer chip 310 and the second molding layer 330. The redistribution layer RDL may extend the input/output terminal of the buffer chip 310 to the outside of the buffer chip 310. For example, the redistribution layer RDL may be electrically connected to the input/output terminal of the buffer chip 310 and extend the input/output terminal to the lower portion of the second molding layer 330.

The outer side surface of the redistribution layer RDL may be coplanar with the outer side surface of the second molding layer 330. The lower pad 380 of the chip structure 300b may be arranged under the redistribution layer RDL and may be electrically connected to the redistribution pattern RP of the redistribution layer RDL. A portion of the lower pad 380 may be arranged outside the buffer chip 310.

The redistribution layer RDL may include the redistribution pattern RP and the redistribution insulating layer RD surrounding the redistribution pattern RP.

The redistribution insulating layer RD may include an insulating material, for example, PID resin. In some embodiments, the redistribution insulating layer RD may further include an inorganic filler. In some embodiments, the redistribution insulating layer RD may have a multilayered structure in which redistribution patterns are arranged at respective layers.

The redistribution pattern RP may include the redistribution line pattern RL extending in the horizontal direction and the redistribution via pattern RV extending from the redistribution line pattern RL in the vertical direction (the Z direction). The redistribution line pattern RL may be arranged on at least one of the upper surface and the lower surface of the redistribution insulating layer RD or arranged inside the redistribution insulating layer RD. The redistribution via pattern RV may penetrate the redistribution insulating layer RD and may be connected to a portion of the redistribution line pattern RL.

The redistribution pattern RP may include a conductive material, for example, Cu, Al, Ag, Sn, Au, Ni, Pb, Ti, or an alloy thereof.

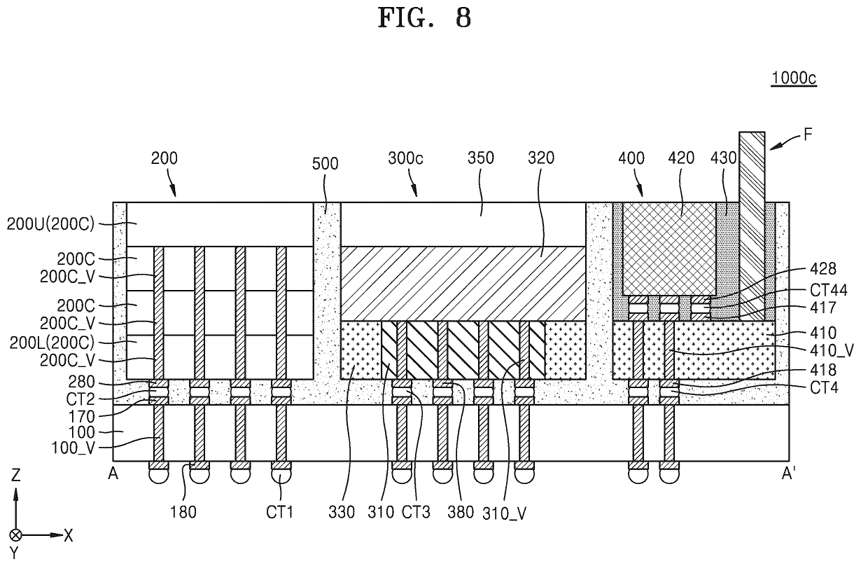

FIG. 8 is a schematic cross-sectional view of a semiconductor package according to an embodiment, taken along the line A-A′ of FIG. 1.

Most of the components forming a semiconductor package 1000c described below and the materials of the components are substantially the same as or similar to those described above with reference to FIG. 2. Therefore, for convenience of explanation, differences between the semiconductor package 1000c of FIG. 8 and the aforementioned semiconductor package 1000 of FIG. 2 are mainly described.

The semiconductor package 1000c may include a chip structure 300c. The chip structure 300c may further include the buffer chip 310, the memory controller chip 320, the second molding layer 330, and a dummy chip 350.

The dummy chip 350 may be arranged on the memory controller chip 320. The dummy chip 350 may include a semiconductor material, such as Si. In some embodiments, the dummy chip 350 may include only a semiconductor material. For example, the dummy chip 350 may be a portion of a bare wafer.

For example, the vertical level of the upper surface of the memory controller chip 320 may be lower than the vertical level of the upper surface of the photonics package 400. In this case, the dummy chip 350 may be arranged on the memory controller chip 320, and thus, the height of the chip structure 300c may be aligned with the height of the photonics package 400. For example, the upper surface of the dummy chip 350 and the upper surface of the EIC chip 420 are prevented from being covered by the third molding layer 500 and thus may be open to the outside.

The upper surface of the dummy chip 350 may be coplanar with the upper surface of the third molding layer 500. The vertical level of the upper surface of the dummy chip 350 may be the same as the vertical level of the upper surface of the third molding layer 500. In some embodiments, the side surface of the dummy chip 350 may be coplanar with the side surface of the memory controller chip 320.

For example, the dummy chip 350 may prevent the upper surface of the memory controller chip 320 from being covered by the third molding layer 500. The dummy chip 350 may help discharge heat, generated by the memory controller chip 320, to the outside.

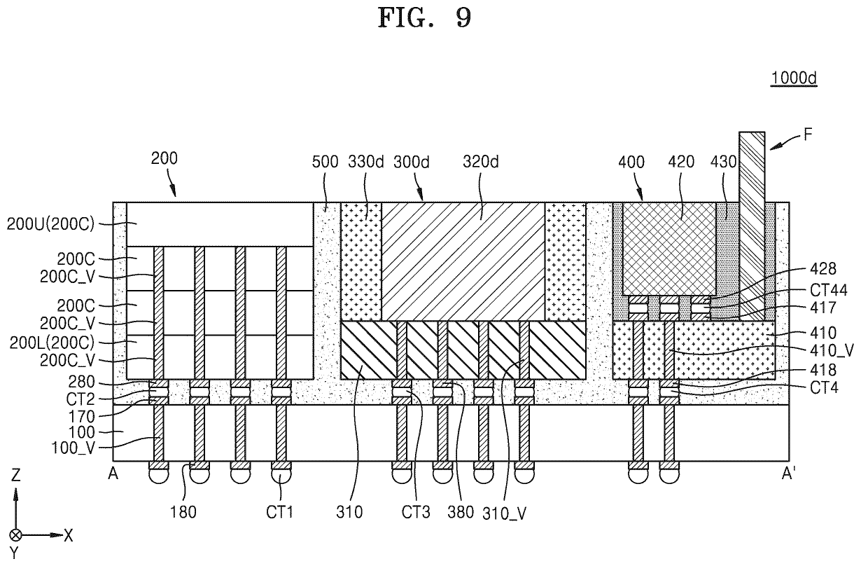

FIG. 9 is a schematic cross-sectional view of a semiconductor package according to an embodiment, taken along the line A-A′ of FIG. 1.

Most of the components forming a semiconductor package 1000d described below and the materials of the components are substantially the same as or similar to those described above with reference to FIG. 2. Therefore, for convenience of explanation, differences between the semiconductor package 1000d of FIG. 9 and the aforementioned semiconductor package 1000 of FIG. 2 are mainly described.

The semiconductor package 1000d may include a chip structure 300d. The chip structure 300d may include the buffer chip 310, a memory controller chip 320d, and a second molding layer 330d. The buffer chip 310 may be arranged on the package substrate 100, and the memory controller chip 320d may be arranged on the buffer chip 310.

The area of the buffer chip 310 may be different from that of the memory controller chip 320d. For example, the area of the buffer chip 310 may be greater than that of the memory controller chip 320d. For example, the side surface of the memory controller chip 320d may be arranged on the upper surface of the buffer chip 310.

The second molding layer 330d may be on the buffer chip 310 and surround the memory controller chip 320d. The outer side surface of the second molding layer 330d may be coplanar with the side surface of the buffer chip 310. The upper surface of the second molding layer 330d may be coplanar with the upper surface of the memory controller chip 320d.

In some embodiments, the chip structure 300d may further include a redistribution layer arranged under the memory controller chip 320d and the second molding layer 330d. The redistribution layer may extend the input/output terminal of the memory controller chip 320d to the outside of the memory controller chip 320d and may electrically connect the input/output terminal to the buffer chip 310.

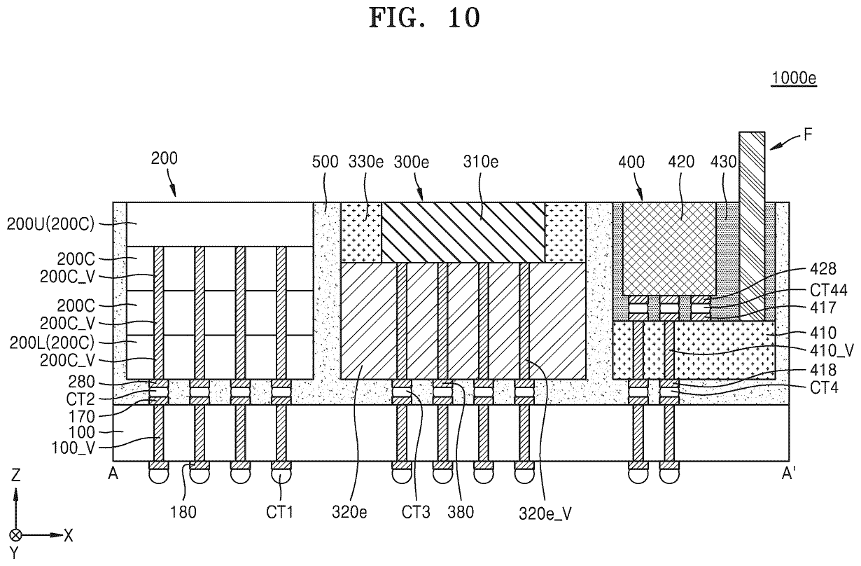

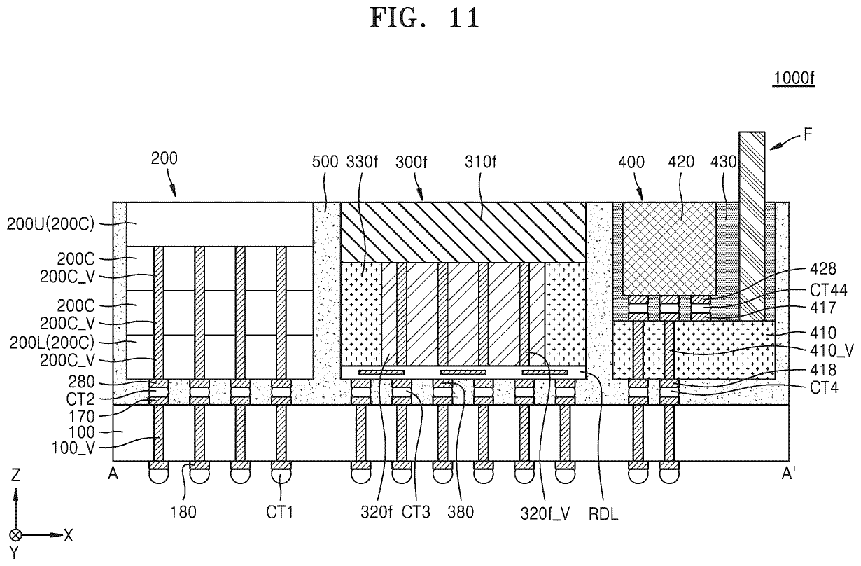

FIG. 10 is a schematic cross-sectional view of a semiconductor package according to an embodiment, taken along the line A-A′ of FIG. 1. FIG. 11 is a schematic cross-sectional view of a semiconductor package according to an embodiment, taken along the line A-A′ of FIG. 1.

Most of the components forming semiconductor packages 1000e and 1000f described below and the materials of the components are substantially the same as or similar to those described above with reference to FIG. 2. Therefore, for convenience of explanation, differences between the semiconductor packages 1000c and 1000f of FIGS. 10 and 11 and the aforementioned semiconductor package 1000 of FIG. 2 are mainly described.

Referring to FIG. 10, a chip structure 300e may include a memory controller chip 320c, a buffer chip 310c, and a second molding layer 330e. The memory controller chip 320e may be on the package substrate 100, and the buffer chip 310e may be on the memory controller chip 320e. The area of the buffer chip 310e may be less than that of the memory controller chip 320e, and the second molding layer 330e may surround the buffer chip 310e on the memory controller chip 320c.

The upper surface of the buffer chip 310e may be coplanar with the upper surface of the second molding layer 330c. That is, the upper surface of the buffer chip 310e may be open to the outside. Accordingly, the heat generated by the buffer chip 310e may be easily discharged to the outside.

The memory controller chip 320e may further include a fourth through via 320c_V extending from the upper surface of the memory controller chip 320e to the lower surface thereof. The fourth through via 320e_V may extend from the active surface of the fourth substrate of the memory controller chip 320e to the inactive surface of the fourth substrate. The fourth through via 320e_V may be electrically connected to the lower pad 380. The buffer chip 310e may be electrically connected to the package substrate 100 through the fourth through via 320e_V.

Referring to FIG. 11, a chip structure 300f may include a buffer chip 310f, a memory controller chip 320f, and a second molding layer 330f. The memory controller chip 320f may be on the package substrate 100, and the buffer chip 310f may be on the memory controller chip 320f.

The area of the memory controller chip 320f may be different from that of the buffer chip 310f. The area of the memory controller chip 320f may be less than that of the buffer chip 310f. The second molding layer 330f may be between the buffer chip 310f and the package substrate 100 and may surround the memory controller chip 320f. The second molding layer 330f may have an outer side surface that is coplanar with the outer surface of the buffer chip 310f.

The memory controller chip 320f may include a fourth through via 320f_V extending from an upper surface of the memory controller chip 320f to a lower surface thereof. The fourth through via 320f_V may be substantially the same as the fourth through via (320c_V, see FIG. 10) described with reference to FIG. 10.

The redistribution layer RDL may be arranged under the memory controller chip 320f and the second molding layer 330f. For example, the redistribution layer RDL may be arranged on the lower surfaces of the memory controller chip 320f and the second molding layer 330f and have the side surface that is coplanar with the outer side surface of the second molding layer 330f.

The redistribution layer RDL may extend the input/output terminal of the memory controller chip 320f to the outside of the memory controller chip 320f. For example, components of the redistribution layer RDL and materials of the components may be substantially the same as those for the redistribution layer RDL described above with reference to FIG. 6.

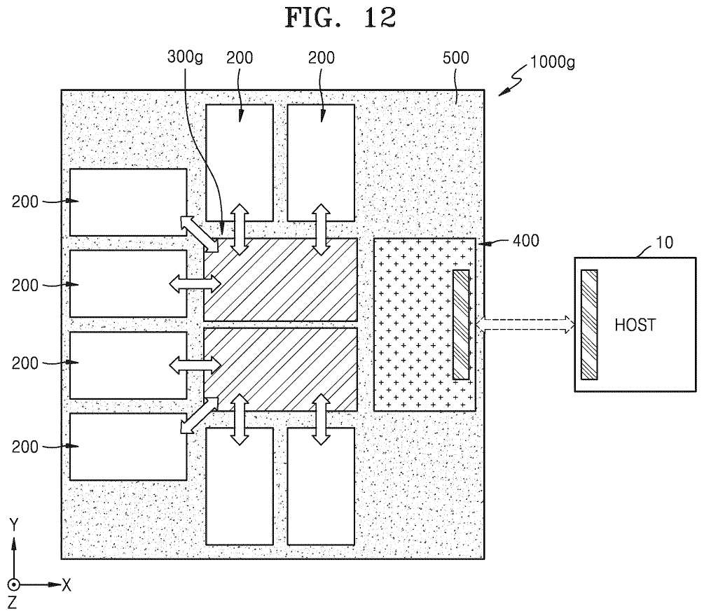

FIG. 12 is a schematic plan view of a semiconductor package according to an embodiment.

Most of the components forming a semiconductor package 1000g described below and the materials of the components are substantially the same as or similar to those described above with reference to FIG. 2. Therefore, for convenience of explanation, differences between the semiconductor package 1000g of FIG. 12 and the aforementioned semiconductor package 1000 of FIG. 2 are mainly described.

The semiconductor package 1000g may include a plurality of chip structures 300g. The chip structures 300g may be spaced apart from each other in the horizontal direction. For example, the third molding layer 500 may be arranged between the chip structures 300g. In some embodiments, the stack structures 200 may surround the chip structures 300g.

The number of chip structures 300g may be less than that of the stack structures 200. For example, each of the chip structures 300g may be electrically connected to at least two stack structures 200. In some embodiments, each stack structure 200 may be electrically connected to one of the chip structures 300g.

In some embodiments, the chip structures 300g may be electrically connected to one photonics package 400. However, one or more embodiments are not limited thereto, and the semiconductor package 1000g may include a plurality of photonics packages 400, and the chip structures 300g may be electrically connected to different photonics packages 400.

In the semiconductor package 1000g, the number of stack structures respectively controlled by the chip structures 300g decreases, and thus, the size of the buffer chip of each chip structure 300g may be reduced. Accordingly, the yield of the buffer chip may increase, and thus, the manufacturing costs of the semiconductor package 1000g may decrease.

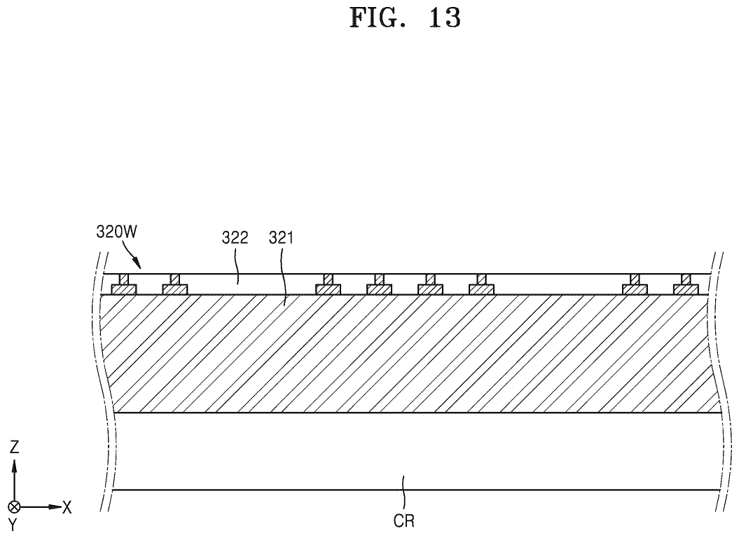

FIGS. 13 to 19 are diagrams showing a method of manufacturing the semiconductor package 1000b in a process order, according to an embodiment.

In detail, FIGS. 13 to 19 are sequential cross-sectional views of the semiconductor package 1000b of FIG. 6, taken along the line A-A′ of FIG. 1, illustrating the manufacturing processes of the semiconductor package 1000b. In particular, FIGS. 13 to 16 are cross-sectional views showing, in sequence, the manufacturing processes of the chip structure 300b of the semiconductor package 1000b of FIG. 6.

Most of the components forming the semiconductor package 1000b described below and the materials of the components are substantially the same as or similar to those described above with reference to FIG. 6. Therefore, for convenience of explanation, descriptions that are the same as those regarding the semiconductor package 1000b of FIG. 6 are omitted.

Referring to FIG. 13, a semiconductor wafer 320W may be attached to a carrier substrate CR by an adhesive insulating layer (not shown).

The carrier substrate CS may include, for example, glass, Si, or aluminum oxide. The adhesive insulating layer may include an arbitrary material used to fix the package substrate 100. The adhesive insulating layer may be, for example, an adhesive tape of which adhesion weakens due to thermal treatment or laser irradiation.

The semiconductor wafer 320W may include the fourth substrate 321 and the fourth wiring structure 322 in a state before the memory controller chip 320 is diced. That is, the memory controller chips 320 may be manufactured by dicing the semiconductor wafer 320W. The semiconductor wafer 320W may be arranged such that the active surface of the fourth substrate 321 faces upwards.

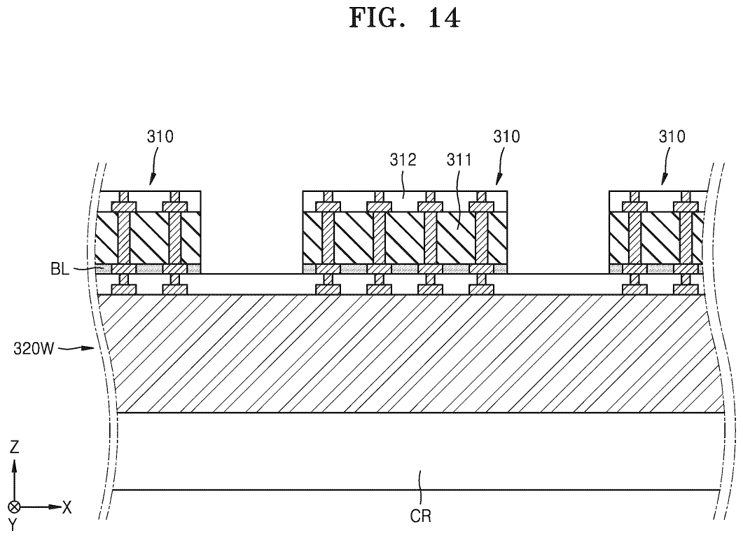

Referring to FIG. 14, a plurality of buffer chips 310 may be attached to the semiconductor wafer 320W. For example, the buffer chip 310 may be attached to the semiconductor wafer 320W in a chip on wafer (COW) manner.

The semiconductor wafer 320W may be electrically connected to the buffer chip 310 through the bonding layer BL. For example, the bonding layer BL may be arranged between the semiconductor wafer 320W and the buffer chip 310. The bonding layer BL may be formed through hybrid bonding.

However, the method by which the buffer chips 310 are attached to the semiconductor wafer 320W is not limited thereto. For example, the semiconductor wafer 320W may be electrically connected to the buffer chips 310 through a connection terminal or an adhesive film.

In some embodiments, one buffer chip may be attached to each cell region of the semiconductor wafer 320W, that is, a region to later become a memory controller chip. However, the number of buffer chips 310 is not limited thereto, and two or more buffer chips 310 may be attached to each cell region of the semiconductor wafer 320W.

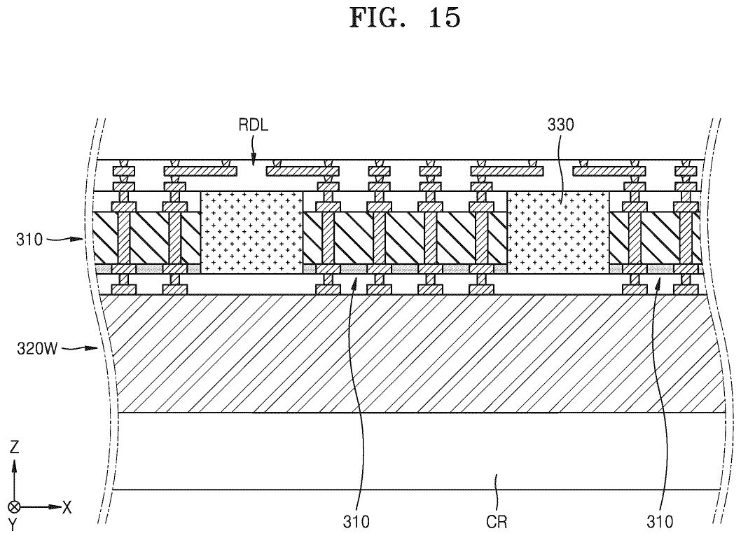

Referring to FIG. 15, the second molding layer 330 and the redistribution layer RDL may be formed.

The second molding layer 330 may be formed on the semiconductor wafer 320W to cover the buffer chip 310. Then, a portion of the second molding layer 330 may be removed such that the third wiring structure 312 of the buffer chip 310 may be exposed to the outside. The second molding layer 330 may protect the buffer chip 310 from the outside.

The redistribution layer RDL may be formed on the buffer chip 310 and the second molding layer 330. The process of forming the redistribution layer RDL may be accomplished through a redistribution process. That is, through the redistribution process, the redistribution insulating layer and the redistribution pattern may be alternately formed on the redistribution layer RDL. In some embodiments, a passivation layer may be formed on the redistribution insulating layer to protect a portion of the redistribution pattern.

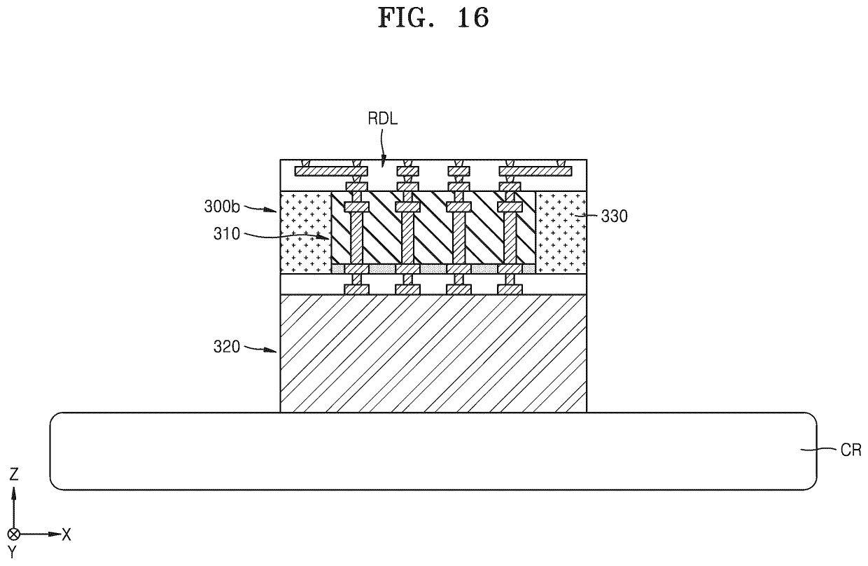

Referring to FIG. 16, the chip structure 300b may be formed by cutting the structure shown in FIG. 15.

In the process of cutting the semiconductor wafer 320W along a planned separation line of the semiconductor wafer 320W, the second molding layer 330 and the redistribution layer RDL formed on the semiconductor wafer 320W may be cut. The chip structures 300b may be formed by cutting the structure shown in FIG. 15 along the planned separation line of the semiconductor wafer 320W. During the process, the side surface of the memory controller chip 320, the outer side surface of the second molding layer 330, and the side surface of the redistribution layer RDL may be formed by cutting to be coplanar with each other.

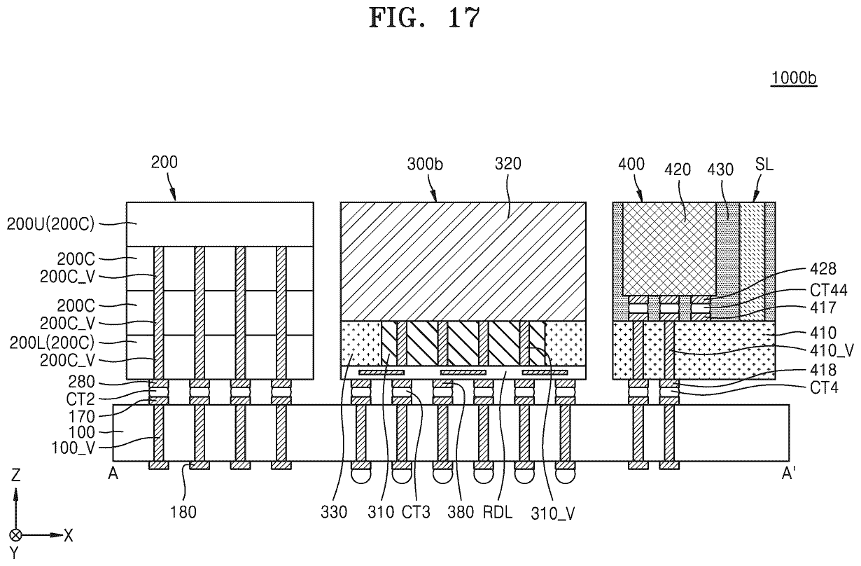

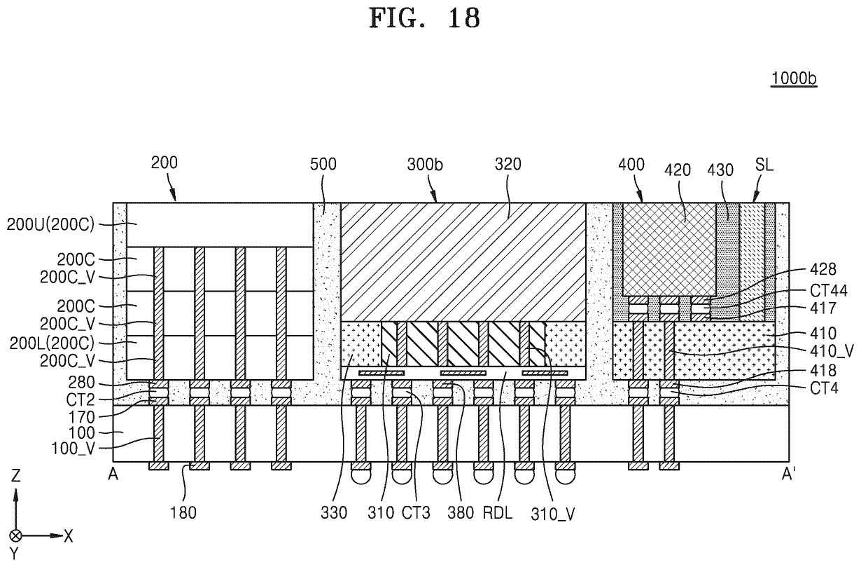

Referring to FIGS. 17 and 18, after the stack structures 200, the chip structure 300b, and the photonics package 400 are mounted on the package substrate 100, the third molding layer 500 may be formed.

The package substrate 100 may be a silicon interposer, a glass interposer, or a PCB.

The stack structures 200, the chip structure 300b, and the photonics package 400 may be horizontally spaced apart from each other on the package substrate 100. For example, the stack structures 200 and the photonics package 400 may be arranged to surround the chip structure 300b.

In some embodiments, the stack structures 200, the chip structure 300b, and the photonics package 400 may be electrically connected to the package substrate 100 through the connection terminals CT2, CT3, and CT4, respectively. However, one or more embodiments are not limited thereto, and the stack structures 200, the chip structure 300b, and the photonics package 400 may be electrically connected to the package substrate 100 through an ACF, an NCF, direct bonding, or hybrid bonding.

Next, after the third molding layer 500 is formed to cover the stack structures 200, the chip structure 300b, and the photonics package 400, a portion of the third molding layer 500 may be removed to externally expose upper surfaces of the stack structures 200, the chip structure 300b, and the photonics package 400. The third molding layer 500 may protect the stack structures 200, the chip structure 300b, and the photonics package 400 from the outside.

Because the curing timing of the third molding layer 500 is different from that of the first molding layer 430, there may be an interface between the first molding layer 430 and the third molding layer 500. For example, the first molding layer 430 may contact the third molding layer 500. Because the curing timing of the third molding layer 500 is different from that of the second molding layer 330, there may be an interface between the second molding layer 330 and the third molding layer 500. For example, the second molding layer 330 may contact the third molding layer 500.

For example, although the first molding layer 430, the second molding layer 330, and the third molding layer 500 include the same material, there may be interfaces between the first molding layer 430 and the third molding layer 500 and between the second molding layer 330 and the third molding layer 500.

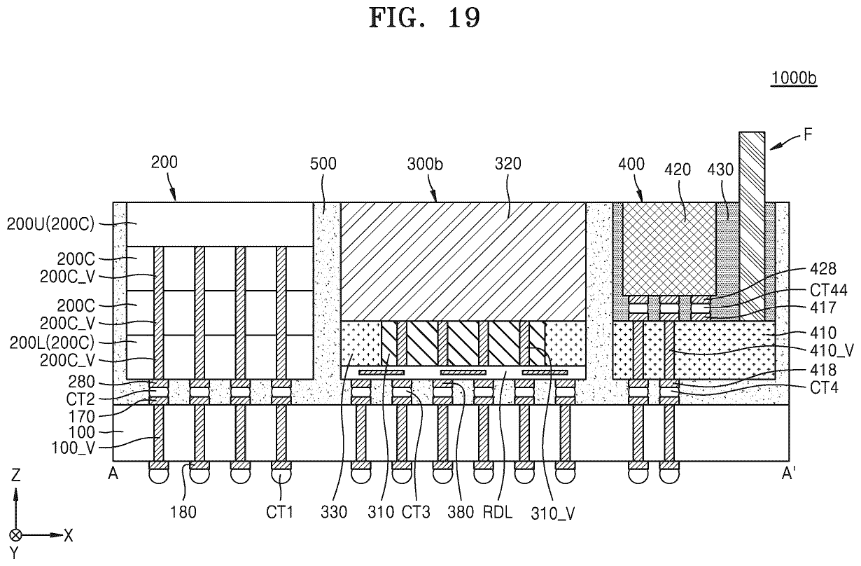

Referring to FIG. 19, a sacrificial layer SL previously formed in the first molding layer 430 may be removed, and the optical fiber F may be attached to the photonics package 400.

The opening may be formed in the first molding layer 430 of the photonics package 400 by removing the sacrificial layer SL. Accordingly, a portion of the waveguide of the PIC chip 410 may be exposed to the outside. The optical fiber F may be attached to the inside of the opening of the first molding layer 430. An end portion of the optical fiber F may face the PIC chip 410 and may be optically connected to the waveguide of the PIC chip 410.

The external connection terminals CT1 may be attached to the lower pad 180 of the package substrate 100. In some embodiments, the external connection terminals CT1 may include, for example, solder balls, conductive bumps, conductive paste, BGA, or a combination thereof.

While the inventive concept has been particularly shown and described with reference to embodiments thereof, it will be understood that various changes in form and details may be made therein without departing from the spirit and scope of the disclosure.

What is claimed is:

1. A semiconductor package comprising:
a package substrate;
a plurality of stack structures on the package substrate;
a buffer chip on the package substrate and spaced apart from the plurality of stack structures in a horizontal direction;
a memory controller chip stacked on the buffer chip; and
a photonics package comprising:
a photonic integrated circuit (PIC) chip on the package substrate,
an electronic integrated circuit (EIC) chip on the PIC chip, and
a first molding layer surrounding the EIC chip,
wherein each of the plurality of stack structures comprises a plurality of stacked core chips each comprising a memory cell,
the buffer chip is configured to control the memory cell of each of the plurality of stacked core chips, and
the memory controller chip is configured to interconnect the buffer chip to the photonics package.

2. The semiconductor package of claim 1, wherein the plurality of stacked core chips each comprise a dynamic random access memory (DRAM) memory cell.

3. The semiconductor package of claim 1, wherein the photonics package is configured to receive and/or transmit an optical signal from and/or to an external host and convert an optical signal into an electrical signal and the electrical signal into the optical signal, and
the memory controller chip is further configured to convert an electrical signal that uses a first protocol, which has been converted from an optical signal by the photonics package, to an electrical signal that uses a second protocol and transmit the electrical signal that uses the second protocol to the buffer chip, and
the memory controller chip is further configured to convert the electrical signal from the buffer chip that uses the second protocol to the electrical signal that uses the first protocol and transmit the electrical signal that uses the first protocol to the photonics package.

4. The semiconductor package of claim 1, wherein the buffer chip further comprises a through via extending from an upper surface of the buffer chip to a lower surface of the buffer chip, and
the photonics package is electrically connected to the memory controller chip through the package substrate and the through via of the buffer chip.

5. The semiconductor package of claim 1, wherein an area of the memory controller chip is greater than an area of the buffer chip when viewed in plan view, and
the semiconductor package further comprises a second molding layer on the package substrate, surrounding the buffer chip, and having an outer side surface that is coplanar with a side surface of the memory controller chip.

6. The semiconductor package of claim 5, further comprising a redistribution layer on a lower surface of the buffer chip and on a lower surface of the second molding layer,
wherein a side surface of the redistribution layer is coplanar with the outer side surface of the second molding layer.

7. The semiconductor package of claim 5, further comprising a through electrode penetrating the second molding layer.

8. The semiconductor package of claim 7, further comprising a third molding layer on the package substrate and surrounding the plurality of stack structures, the memory controller chip, the second molding layer, and the photonics package.

9. The semiconductor package of claim 8, wherein the third molding layer contacts the first molding layer of the photonics package, and
the third molding layer contacts the second molding layer.

10. The semiconductor package of claim 1, further comprising a dummy chip on the memory controller chip,
wherein a vertical level of an upper surface of the dummy chip is the same as a vertical level of an upper surface of the photonics package.

11. A semiconductor package comprising:
a package substrate;
a plurality of stack structures on the package substrate;
a chip structure on the package substrate, spaced apart from the plurality of stack structures in a horizontal direction, the chip structure comprising a memory controller chip and a buffer chip which have different areas when viewed in plan view; and
a photonics package configured to receive and/or transmit an optical signal from and/or to an external host, convert an optical signal into an electrical signal, and convert an electrical signal into an optical signal,
wherein each of the plurality of stack structures comprises a plurality of stacked core chips each comprising a memory cell,
the buffer chip of the chip structure is configured to control the memory cell of each of the plurality of stacked core chips of each of the plurality of stack structures,
the memory controller chip of the chip structure is configured to interconnect the photonics package to the buffer chip, and
the chip structure further comprises a molding layer surrounding a chip with a smaller area among the buffer chip and the memory controller chip.

12. The semiconductor package of claim 11, wherein the memory controller chip is arranged on the package substrate,
the buffer chip is on the memory controller chip, and
the memory controller chip further comprises a through via extending from an upper surface of the memory controller chip to a lower surface of the memory controller chip.

13. The semiconductor package of claim 12, wherein when viewed in plan view, an area of the memory controller chip is less than an area of the buffer chip,
the molding layer of the chip structure is arranged on the package substrate, surrounds the memory controller chip, and has an outer side surface that is coplanar with a side surface of the buffer chip, and
the chip structure further comprises a redistribution layer on a lower surface of the memory controller chip and on a lower surface of the molding layer, the redistribution layer having has a side surface that is coplanar with the outer side surface of the molding layer.

14. The semiconductor package of claim 11, wherein the chip structure is located in a central region of the package substrate, and
the plurality of stack structures and the photonics package are located in edge regions of the package substrate.

15. The semiconductor package of claim 14, wherein when viewed in plan view, an area of each core chip of each of the plurality of stack structures is less than an area of the chip structure.

16. The semiconductor package of claim 11, wherein a side surface of the chip structure faces the photonics package, and
the remaining side surfaces of the chip structure face the plurality of stack structures.

17. The semiconductor package of claim 11, wherein the buffer chip and the memory controller chip of the chip structure are electrically connected to each other through hybrid bonding.

18. A semiconductor package comprising:
a package substrate;
a plurality of stack structures on the package substrate;
a chip structure on the package substrate, spaced apart from the plurality of stack structures in a horizontal direction, the chip structure comprising a buffer chip and a memory controller chip which have different areas from each other when viewed in plan view;
a photonics package comprising:
a photonic integrated circuit (PIC) chip on the package substrate,
an electronic integrated circuit (EIC) chip on the PIC chip, and
a first molding layer surrounding the EIC chip; and
a third molding layer on the package substrate and surrounding the plurality of stack structures, the chip structure, and the photonics package,
wherein the photonics package is configured to receive and/or transmit an optical signal from and/or to an external host and convert an optical signal into an electrical signal and an electrical signal into an optical signal,
the memory controller chip of the chip structure is configured to convert an electrical signal that uses a first protocol, which has been converted from an optical signal by the photonics package, to an electrical signal that uses a second protocol, and to convert an electrical signal from the buffer chip that uses the second protocol to the electrical signal that uses the first protocol,
each of the plurality of stack structures comprises a plurality of stacked core chips each comprising a dynamic random access memory (DRAM) cell,
the buffer chip of the chip structure is configured to control the DRAM cell of each of the plurality of stacked core chips of each of the plurality of stack structures,
the chip structure further comprises a second molding layer surrounding a chip with a smaller area among the buffer chip and the memory controller chip,
the third molding layer contacts the second molding layer, and
the third molding layer contacts the first molding layer.

19. The semiconductor package of claim 18, wherein the buffer chip of the chip structure is on the package substrate,
the memory controller chip is arranged on the buffer chip,
the buffer chip has an area when viewed in plan view that is less than an area of the memory controller chip,
the second molding layer surrounds the buffer chip and has an outer side surface that is coplanar with a side surface of the memory controller chip, and
the chip structure further comprises a redistribution layer on a lower surface of the buffer chip and a lower surface of the second molding layer.

20. The semiconductor package of claim 18, wherein the first molding layer of the photonics package further comprises an opening extending from an upper surface of the first molding layer to an inside thereof, and
a waveguide of the PIC chip is externally exposed through the opening.
